(19) United States
(12) Patent Application Publication
(10) Pub. No.: US 2016/0268409 A1
(43) Pub. Date: Sep. 15, 2016

(54) SEMICONDUCTOR DEVICE AND MANUFACTURING METHOD THEREOF

(71) Applicant: KABUSHIKI KAISHA TOSHIBA, Tokyo (JP)

(72) Inventors: Masaaki OGAWA, Sagamihara Kanagawa (JP); Hitoshi KOBAYASHI, Hakusan Ishikawa (JP)

(21) Appl. No.: 14/840,777

(22) Filed: Aug. 31, 2015

(30) Foreign Application Priority Data
Mar. 13, 2015 (JP) 2015-051464

(51) Int. Cl. H01L 29/778; H01L 29/205; H01L 21/3065; H01L 21/28; H01L 21/324; H01L 29/66; H01L 29/45

(52) U.S. Cl. CPC H01L 29/7787; H01L 29/66462; H01L 29/205; H01L 29/452; H01L 21/28052; H01L 21/324; H01L 21/3065

(57) ABSTRACT

A semiconductor device includes a first nitride semiconductor layer, a second nitride semiconductor layer located on the first nitride semiconductor layer, a first electrode on the second nitride semiconductor layer, a second electrode on the second nitride semiconductor layer, a p-type third nitride semiconductor layer on the second nitride semiconductor layer between the first electrode and the second electrode and in contact with the second nitride semiconductor layer, and a third electrode containing p-type polysilicon on the third nitride semiconductor layer and in contact with the third nitride semiconductor layer.

### CROSS-REFERENCE TO RELATED APPLICATION

This application is based upon and claims the benefit of priority from Japanese Patent Application No. 2015-051464, filed Mar. 13, 2015, the entire contents of which are incorporated herein by reference.

### FIELD

Embodiments described herein relate generally to a semiconductor device and a manufacturing method thereof.

### BACKGROUND

In a semiconductor device such as a High Electron Mobility Transistor (HEMT), for example, a nitride semiconductor is used as a material thereof. This semiconductor device is in a normally-off state because a p-type nitride semiconductor layer is interposed between the gate electrode and the barrier layer thereof.

In order to improve controllability of the switching operation of such a semiconductor device, it is preferable that the resistance between the gate electrode and the p-type nitride semiconductor layer be further reduced.

### DESCRIPTION OF THE DRAWINGS

FIG. 1A is a schematic cross-sectional view illustrating a main portion of a semiconductor device according to a first embodiment. FIG. 1B is a schematic top plan view illustrating a main portion of the semiconductor device according to the first embodiment.

FIGS. 2A to 2C are schematic cross-sectional views illustrating a manufacturing process of the main portion of the semiconductor device according to the first embodiment.

FIGS. 3A to 3C are schematic cross-sectional views illustrating the manufacturing process of the main portion of the semiconductor device according to the first embodiment.

FIGS. 4A and 4B are schematic cross-sectional views illustrating the manufacturing process of the main portion of the semiconductor device according to the first embodiment.

FIGS. 5A to 5C are schematic cross-sectional views illustrating the manufacturing process of a gate electrode according to a reference example.

FIG. 6 is a schematic cross-sectional view illustrating a main portion of a semiconductor device according to a second embodiment.

FIGS. 7A to 7C are schematic cross-sectional views illustrating a manufacturing process of the main portion of the semiconductor device according to the second embodiment.

FIGS. 8A and 8B are schematic cross-sectional views illustrating the manufacturing process of the main portion of the semiconductor device according to the second embodiment.

FIGS. 9A and 9B are schematic cross-sectional views illustrating a manufacturing process of a main portion of a semiconductor device according to a third embodiment.

FIGS. 10A and 10B are schematic cross-sectional views illustrating the manufacturing process of the main portion of the semiconductor device according to the third embodiment.

FIGS. 11A to 11C are schematic cross-sectional views illustrating a manufacturing process of a main portion of a semiconductor device according to a fourth embodiment.

FIGS. 12A to 12C are schematic cross-sectional views illustrating the manufacturing process of the main portion of the semiconductor device according to the fourth embodiment.

### DETAILED DESCRIPTION

Embodiments provide a semiconductor device capable of reducing the electrical resistance between a gate electrode and a p-type nitride semiconductor layer and the manufacturing method thereof.

In general, according to a first embodiment, a semiconductor device includes a first nitride semiconductor layer, a second nitride semiconductor layer on the first nitride semiconductor layer, a first electrode on the second nitride semiconductor layer, a second electrode on the second nitride semiconductor layer, a p-type third nitride semiconductor layer on the second nitride semiconductor layer, between the first electrode and the second electrode and in contact with the second nitride semiconductor layer, and a third electrode containing p-type polysilicon, on the third nitride semiconductor layer and in contact with the third nitride semiconductor layer.

Hereinafter, preferred embodiments will be described with reference to the drawings. In the following description, the same reference numbers are attached to the same elements and features, and a repeated description as for the same materials is omitted where appropriate.

### First Embodiment

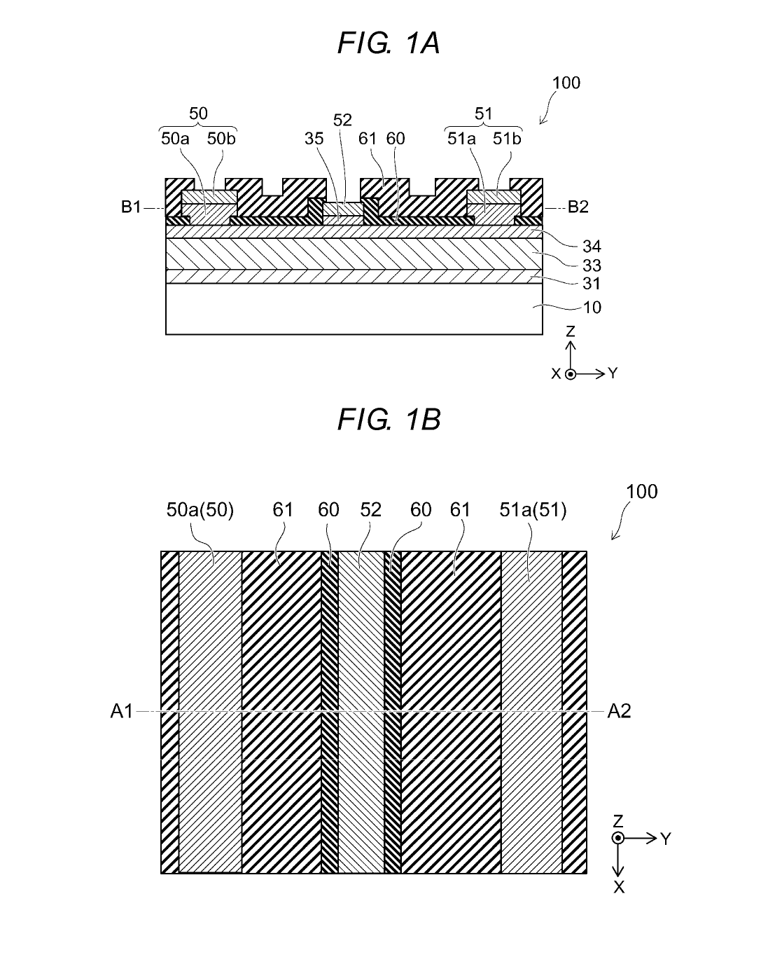

FIG. 1A is a schematic cross-sectional view illustrating a main portion of a semiconductor device according to a first embodiment. FIG. 1B is a schematic top plan view illustrating the main portion of the semiconductor device according to the first embodiment. FIG. 1A illustrates a cross section taken along the line A1-A2 of FIG. 1B. FIG. 1B illustrates a cross section taken along the line B1-B2 of FIG. 1A.

As a semiconductor device 100 according to the first embodiment, a normally-off type High Electron Mobility Transistor (HEMT) is exemplified as one example. The semiconductor device 100 includes a substrate 10, a buffer layer 31, a first nitride semiconductor layer (hereinafter, for example, carrier transport layer 33), a second nitride semiconductor layer (hereinafter, for example, barrier layer 34), a first electrode (hereinafter, for example, source electrode 50), a second electrode (hereinafter, for example, drain electrode 51), a third nitride semiconductor layer (hereinafter, for example, p-type GaN layer 35), and a third electrode (hereinafter, for example, gate electrode 52).

The substrate 10 includes, for example, silicon (Si). The buffer layer 31 is provided on the substrate 10. The buffer layer 31 includes aluminum nitride.

The carrier transport layer 33 is provided on the buffer layer 31. The barrier layer 34 is provided on the carrier transport layer 33. The carrier transport layer 33 includes undoped gallium nitride (GaN), or undoped gallium aluminum nitride (AlₓGa₁₋ₓN (0≦X<1)). The barrier layer 34 includes undoped or n-type gallium aluminum nitride Al_{y}Ga_{1-y}N (0<Y≦1, X<Y)). Two dimensional electron gas (2DEG) is generated in the carrier transport layer 33 in the vicinity of the boundary of the carrier transport layer 33 and the barrier layer 34.

The source electrode 50 is provided on the barrier layer 34. The source electrode 50 includes, for example, a barrier 50a containing titanium (Ti) and an electrode 50b containing aluminum (Al). The source electrode 50 is connected to the barrier layer 34. The source electrode 50 forms an ohmic contact with the barrier layer 34. The source electrode 50 extends, for example, in the X direction.

The drain electrode 51 is provided on the barrier layer 34 at a distance from the source electrode 50. The drain electrode 51 includes, for example, a barrier 51a containing titanium (Ti) and an electrode 51b containing aluminum (Al). The drain electrode 51 is connected to the barrier layer 34. The drain electrode 51 forms an ohmic contact with the barrier layer 34. The drain electrode 51 is provided alongside of the source electrode 50 and spaced therefrom in the Y direction. The drain electrode 51 extends in the X direction generally parallel to the source electrode 50.

A p-type GaN layer 35 is provided on the barrier layer 34. The p-type GaN layer 35 contains p-type gallium nitride (GaN). The dopant element contained in the p-type GaN layer 35 is, for example, magnesium (Mg) and zinc (Zn). The p-type GaN layer 35 is provided at a location between, and spaced from, the source electrode 50 and the drain electrode 51. The p-type GaN layer 35 is connected to the barrier layer 34. The p-type GaN layer 35 likewise extends in the X direction.

By providing the p-type GaN layer 35 on the undoped or n-type barrier layer 34, the potential under the p-type GaN layer 35 is raised and the Fermi level under the p-type GaN layer 35 is raised. Owing to this, under the p-type GaN layer 35, the 2DEG electron cloud moves to a side of the barrier layer 34-carrier layer 33 interface having a lower potential, in other words, in the direction away from the p-type GaN layer 35 and as a result the semiconductor device 100 becomes a normally-off device.

The gate electrode 52 is provided on the p-type GaN layer 35. The gate electrode 52 forms an ohmic contact with the p-type GaN layer 35. The gate electrode 52 contains p-type polysilicon. The p-type dopant element is, for example, boron (B). The gate electrode 52 extends, for example, in the X direction.

Additionally, in the semiconductor device 100, a protective layer 60 is provided on the barrier layer 34. An interlayer insulating layer 61 is provided on the protective layer 60. The protective layer 60 contains, for example, silicon nitride (SiNₓ). The interlayer insulating layer 61 contains, for example, silicon oxide (SiOₓ).

The number of the source electrodes 50, the drain electrodes 51, the p-type GaN layers 35, and the gate electrodes 52 is not restricted to the illustrated number.

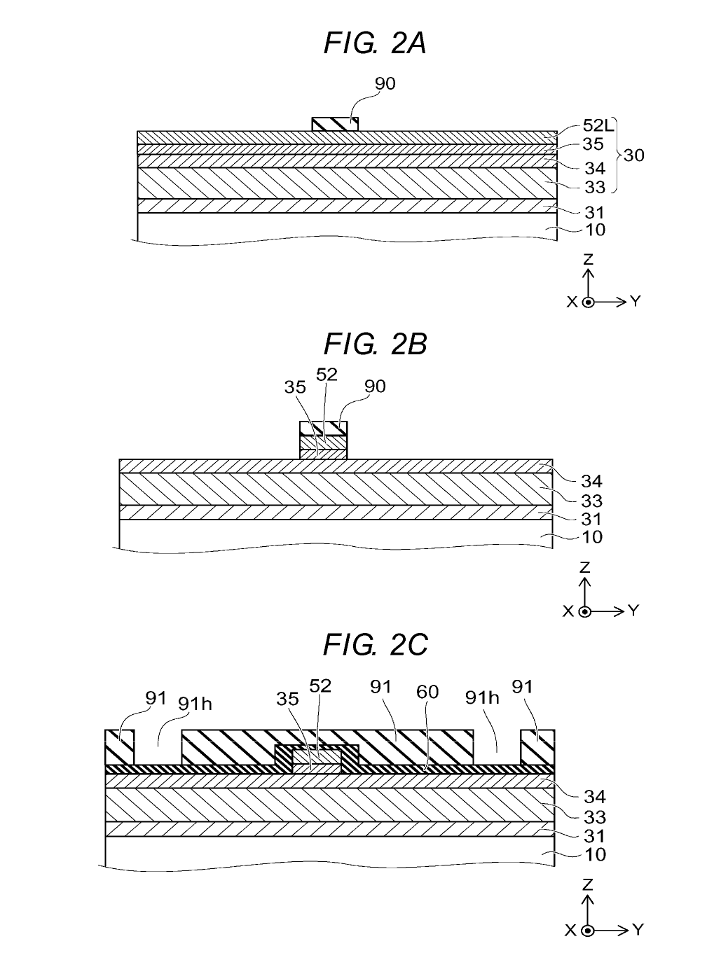

FIGS. 2A to 4B are schematic cross-sectional views illustrating the manufacturing process of a main portion of the semiconductor device according to the first embodiment.

For example, as illustrated in FIG. 2A, the buffer layer 31 is formed on the substrate 10 such as by a metal-organic chemical vapor deposition (MOCVD) process, and the carrier transport layer 33, the barrier layer 34, and the p-type GaN layer 35 are epitaxially grown on the buffer layer 31 in that order. A first layer 52L containing p-type polysilicon is formed on the whole surface of the p-type GaN layer 35. The first layer 52L will form the gate electrode 52 after further processing. The first layer 52L is formed, for example, by low-pressure Chemical Vapor Deposition (CVD) or Atomic Layer Deposition (ALD) of polysilicon. Further, the first layer 52L may be formed by ion implantation of boron into an undoped polysilicon layer and heating in the implanted layer in a nitrogen (N₂) atmosphere. The heating temperature is 800° C. to 900° C.

The carrier transport layer 33, the barrier layer 34, the p-type GaN layer 35, and the gate electrode 52 are formed in a stacked body 30. A mask layer 90 is formed on the gate electrode material layer 52L.

Next, as illustrated in FIG. 2B, the portion of the first layer 52L not covered by the mask layer 90 and the p-type GaN layer 35 under the first layer 52L not covered by the mask layer 90 are selectively removed by Reactive Ion Etching (RIE). As the etching gas, a mixed gas of, for example, a Cl based gas and an F based gas is used. Owing to this, the p-type GaN layer 35 and the gate electrode layer 52L containing the p-type polysilicon are selectively formed on the barrier layer 34. Thereafter, the mask layer 90 is removed.

Then, as illustrated in FIG. 2C, the material to form the protective layer 60 is formed on the barrier layer 34 and the gate electrode 52. Further, a mask layer 91 is formed on the layer of material used to form the protective layer 60. Openings 91h are provided on the mask layer 91 at the respective positions of forming the source electrode 50 and the drain electrode 51.

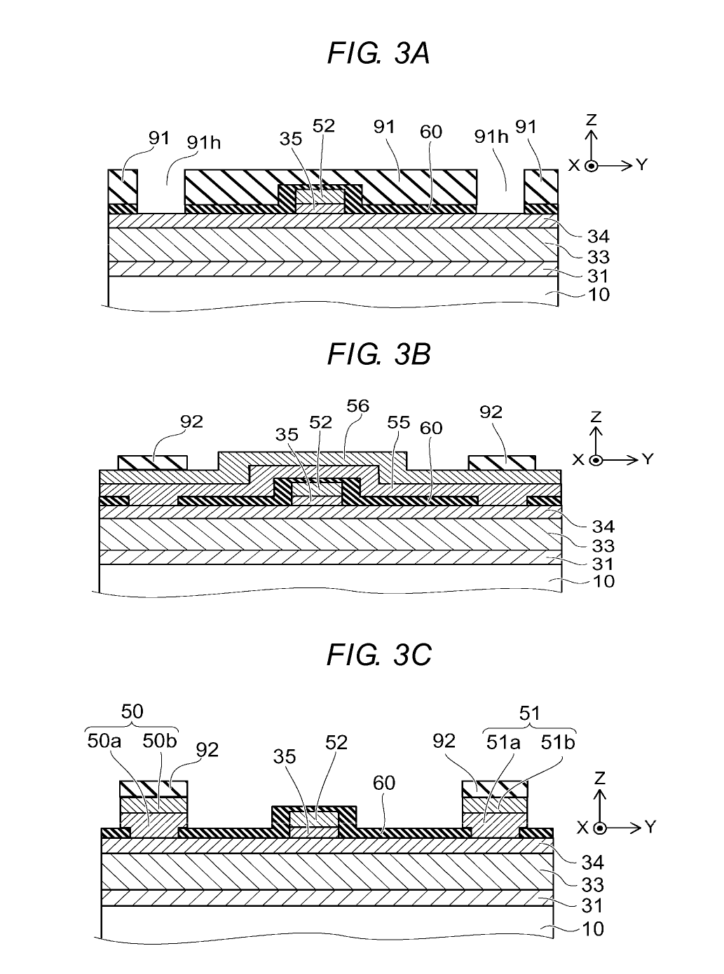

The protective layer 60 exposed by the openings 91h in the mask layer 91 is removed by RIE, as shown in FIG. 3A. Then, the mask layer 91 is removed.

As illustrated in FIG. 3B, a conductive layer 55 containing titanium and a conductive layer 56 containing aluminum are formed in this order on the barrier layer 34 and the protective layer 60. Further, a mask layer 92 is formed on the conductive layer 56. The mask layer 92 is formed, for example, at each position where a source electrode 50 and a drain electrode 51 are to be formed.

Then, as illustrated in FIG. 3C, the exposed portions of the conductive layer 56 and the conductive layer 55 under the conductive layer 56 are removed by RIE. Owing to this, the conductive layer 56 is divided into the electrode 50b and the electrode 51b and the conductive layer 55 is divided into the barrier 50a and the barrier 51a. That is, the source electrode 50 and the drain electrode 51 are formed on the barrier layer 34 to sandwich the gate electrode 52. Then, the mask layer 92 is removed.

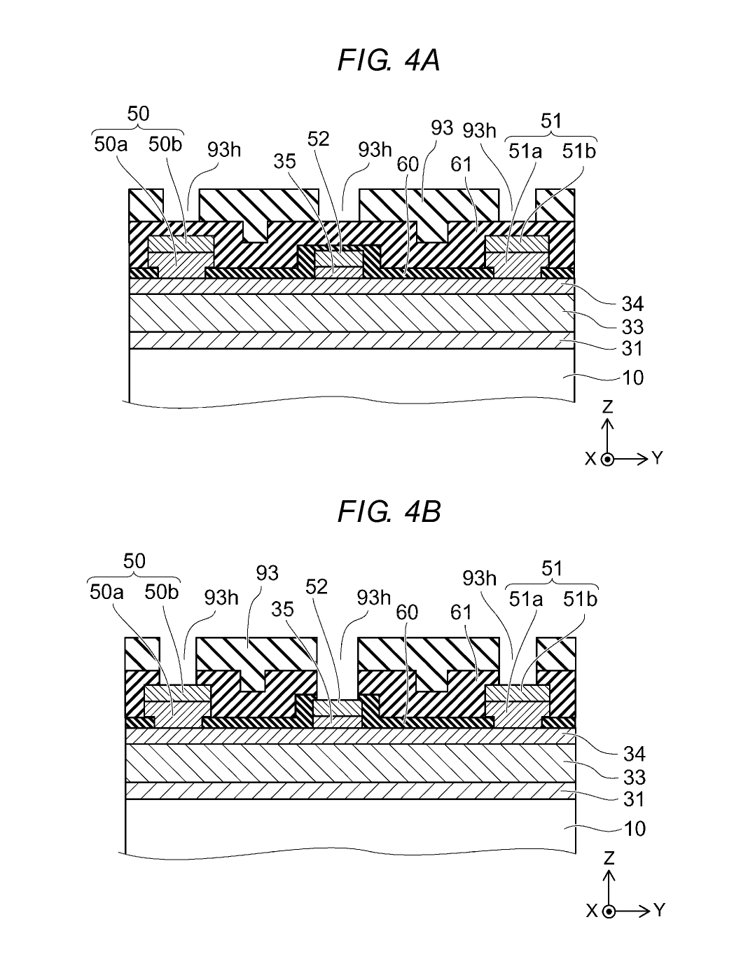

Next, as illustrated in FIG. 4A, an interlayer insulating layer 61 is formed on the source electrode 50 and the drain electrode 51. Further, a mask layer 93 is formed on the interlayer insulating layer 61. The mask layer 93 is provided with openings 93h respectively opening over the source electrode 50, the drain electrode 51, and the gate electrode 52.

As illustrated in FIG. 4B, the exposed portions of the interlayer insulating layer 61 on both the source electrode 50 and the drain electrode 51 are removed by RIE. Further, the exposed portions of the interlayer insulating layer 61 and the protective layer 60 on the gate electrode 52 are removed by RIE. Thereafter, the mask layer 93 is removed.

Then, the interface between the source electrode 50 and the barrier layer 34 and the interface between the drain electrode 51 and the barrier layer 34 may be heated, to diffuse the metal inside the barriers 50a and 51a into the surface of the barrier layer 34 in contact with the source electrode 50 and the drain electrode 51. This heating processing is referred to as contact annealing in the embodiment. Owing to this, the contact resistance is reduced between the source electrode 50 and the barrier layer 34 and between the drain electrode 51 and the barrier layer 34.

In the semiconductor device 100 according to the first embodiment, the gate electrode 52 containing p-type polysilicon is provided on the p-type GaN layer 35. This gate electrode 52 is in contact with the p-type GaN layer 35. The work function of the p-type polysilicon is 5.0 to 5.1 eV, and the work function of the p-type GaN is 4.5 to 7.0 eV. The work function of the p-type polysilicon is within the range of the work function of the p-type GaN. Work function is defined as the energy required to remove an electron from the highest filled level in the Fermi distribution of a solid so that it is stationary at a point in a field-free zone just outside the solid at absolute zero. Accordingly, the gate electrode 52 according to the first embodiment forms an ohmic contact with the p-type GaN layer 35. For example, the contact resistance between the gate electrode 52 and the p-type GaN layer 35 according to the first embodiment is 1×10⁻³ Ω·cm² or less.

Here, assuming that the material of the gate electrode 52 is an n-type polysilicon, the work function of n-type polysilicon is about 4.0. That is, the work function of the n-type polysilicon is smaller than the work function of the p-type GaN. Accordingly, when the gate electrode 52 is n-type polysilicon electrode, a potential barrier is generated between the gate electrode 52 and the p-type GaN layer 35. In other words, a resistance between the gate electrode 52 and the p-type GaN layer 35 does not form effective ohmic contact and the resistance between the gate electrode 52 and the p-type GaN layer 35 is high, as compared to the semiconductor device 100.

Before describing another effect of the first embodiment, a manufacturing process of a semiconductor device according to a reference example will be described.

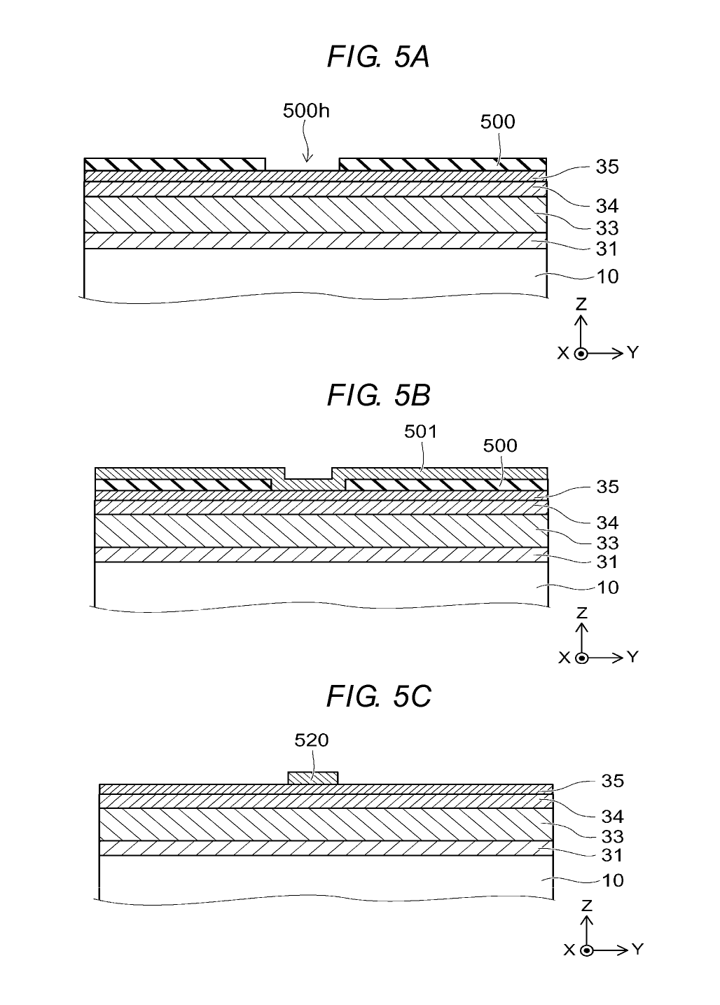

FIGS. 5A to 5C are schematic cross-sectional views illustrating the manufacturing process of a gate electrode according to the reference example.

In the reference example, as the material of the gate electrode 52, one of the noble metals, platinum (Pt) is used. When using platinum (Pt), the work function of the platinum (Pt) is larger than that of the p-type GaN and the gate electrode 52 forms an ohmic contact with the p-type GaN layer 35. However, it is difficult to etch platinum, and thus in the reference example, the gate electrode 52 is formed by lift-off processing.

For example, as illustrated in FIG. 5A, the buffer layer 31 is formed on the substrate 10, and the carrier transport layer 33, the barrier layer 34, and the p-type GaN layer 35 are epitaxially grown on the buffer layer 31 in this order. Further, a mask layer 500 including a resist is formed on the p-type GaN layer 35. The mask layer 500 is provided with an opening 500h on the p-type GaN layer 35 at a position where the gate electrode 52 is located.

Then, as illustrated in FIG. 5B, a platinum film 501 is formed on the mask layer 500 and the p-type GaN layer 35.

As illustrated in FIG. 5C, the mask layer 500 is exposed to an organic solvent and ultrasonic energy is applied to the mask layer 500, which causes the mask layer 500 to dissolve and allows the platinum film 501 overlying the mask layer 500 to be removed. As a result, a gate electrode 520 containing platinum (Pt) is formed on the p-type GaN layer 35.

In the method of patterning the gate electrode 520 using the lift off process of the reference example, there is a possibility that the platinum film 501 on the p-type GaN layer 35 may also be removed during the removal of the mask layer 500. This phenomenon becomes more likely as the width of the gate electrode 520 gets narrower. Additionally, portions of the platinum film 501 removed together with the mask layer 500 may remain within the semiconductor device as contaminating particulates.

In contrast, in the first embodiment, the p-type polysilicon used as the material of the gate electrode 52 is easily processed by RIE. The gate electrode 52 is processed by photolithographically forming a patterned mask, followed by RIE, not the lift-off processing of the reference example. That is, precise and reliable processing of the gate electrode 52 is possible.

Here, assume that as the material of the gate electrode 52, not a precious metal such as platinum but aluminum (Al) which is easily processed by RIE is used. In this case, however, the temperature of the contact annealing exceeds the melting point of the aluminum in some cases. Owing to this, the gate electrode itself melts and the shape of the gate electrode once solidified again may be different from the original shape before melting. In contrast, in the first embodiment, the p-type polysilicon is used as the material of the gate electrode 52 does not melt at the temperature of the heating processing.

Further, in the semiconductor device 100, the gate electrode 52 is directly in contact with the p-type GaN layer 35. For example, when a dielectric layer is interposed between the gate electrode 52 and the p-type GaN layer 35, the potential of the threshold value of the gate electrode 52 gets higher adjacent to the potential barrier provided by the dielectric layer. On the contrary, in the semiconductor device 100, the gate electrode 52 is directly in contact with the p-type GaN layer 35. Owing to this, the potential of the threshold value of the gate electrode 52 may be set as being low. For example, the potential of the threshold voltage of the semiconductor device 100 is 1.0 to 2.0 V.

Further, the gate electrode 52 is p-type polysilicon and therefore, even when performing the heat processing on the protective layer 60, metal does not diffuse from the gate electrode 52 into the protective layer 60. Further, by performing the heat processing on the protective layer 60, the protective layer 60 becomes denser. That is, according to the first embodiment, a highly insulative protective layer 60 may be obtained.

### Second Embodiment

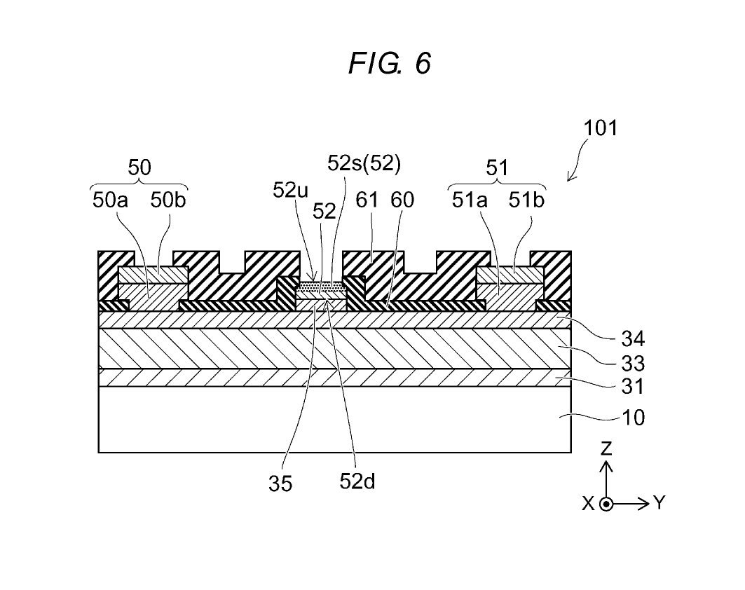

FIG. 6 is a schematic cross-sectional view illustrating a main portion of a semiconductor device according to a second embodiment.

In a semiconductor device 101, the gate electrode 52 containing the p-type polysilicon further contains metal in at least a portion thereof. The metal includes, for example, nickel (Ni) or titanium (Ti). The concentration of the metal at the upper end 52u of the gate electrode is higher than that at the lower end 52d thereof. By annealing (heat processing) the gate electrode structure including the p-type polysilicon with a metal layer thereover, a silicide of the metal, silicide layer 52s, is formed at the upper side of the gate electrode 52.

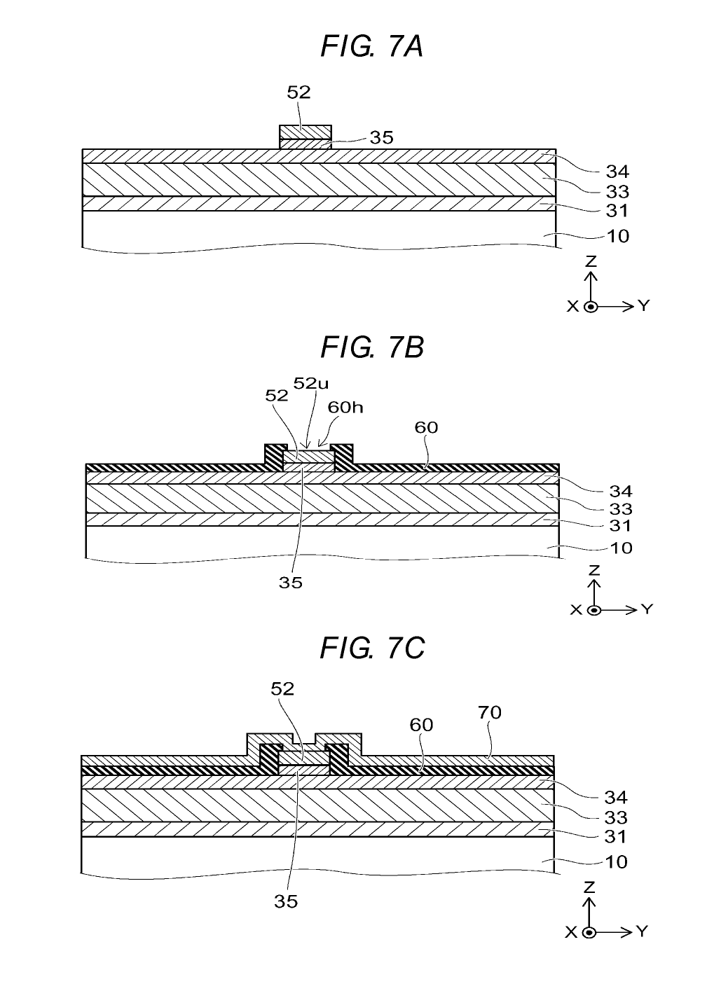

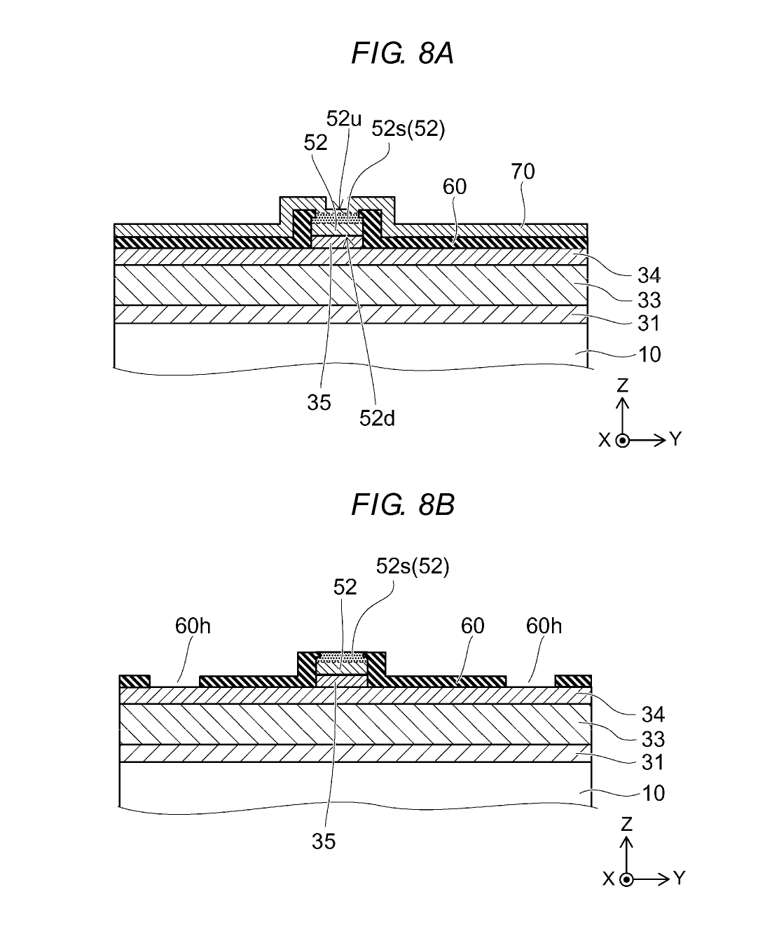

FIGS. 7A to 8B are schematic cross-sectional views illustrating the manufacturing process of a main portion of the semiconductor device according to the second embodiment.

For example, as illustrated in FIG. 7A, the p-type GaN layer 35 and the material to form the polysilicon gate electrode 52 are formed on the barrier layer 34.

As illustrated in FIG. 7B, the protective layer 60 is formed on the barrier layer 34. The protective layer 60 is provided with an opening 60h which opens the upper end 52u of the gate electrode 52. The opening 60h is formed by forming a mask layer, using photolithographic techniques to pattern the mask, and then performing RIE to form an opening in the protective layer 60 down to the upper surface 52u of the polysilicon gate electrode 52.

As illustrated in FIG. 7C, a metal film 70 is formed on the protective layer 60 and the upper surface 52u of the gate electrode 52 by the sputtering method. The metal film 70 contains, for example, nickel (Ni) or titanium (Ti).

As illustrated in FIG. 8A, the gate electrode 52 and the metal film 70 are heated and a silicide layer 52s of the metal and the silicon of the gate 52 is formed on the upper side 52u of the gate electrode 52. The gate electrode 52 is heated so that the metal concentration therein may be higher in the upper end 52u than in the lower end 52d. The heating condition is, for example, at 350° C. for 30 seconds in the nitrogen (N₂) atmosphere, such that metal does not diffuse fully through the polysilicon gate 52 to reach the underlying barrier layer 34. Then, the metal film 70 on the protective layer 60 is removed using sulfuric or ammonia solution. Thereafter, the heating processing may be performed on the silicide layer 52s. The heating condition is, for example, at 500° C. for 30 seconds in the nitrogen (N₂) atmosphere.

As illustrated in FIG. 8B, openings 60h are formed on through the protective layer 60 by PEP and RIE. The openings 60h are formed at the respective positions of forming the source electrode 50 and drain electrode 51.

Then, as illustrated in FIG. 6, the source electrode 50 and the drain electrode 51 are formed on the barrier layer 34. Further, the interlayer insulating layer 61 is formed on the protective layer 60. Further, the bottom of the source electrode 50 and the bottom of the drain electrode 51 are heated and the metal within the barriers 50a and 51a may be diffused between the source electrode 50 and the barrier layer 34 and between the drain electrode 51 and the barrier layer 34. Owing to this, a contact resistance between the source electrode 50 and the barrier layer 34 and between the drain electrode 51 and the barrier layer 34 is reduced.

When the carrier concentration of the p-type polysilicon layer is 1×10²⁰ (atoms/cm³), the resistivity is about 1×10³ (Ω·cm). In the second embodiment, the silicide layer 52s is formed on the upper side of the gate electrode 52. Owing to this, the resistivity of the gate electrode 52 is reduced to 10 to 20 μΩ·cm.

Further, the silicide layer 52s is automatically formed and therefore, there is no need for lithographic masking and RIE processes to form the silicide layer 52s.

### Third Embodiment

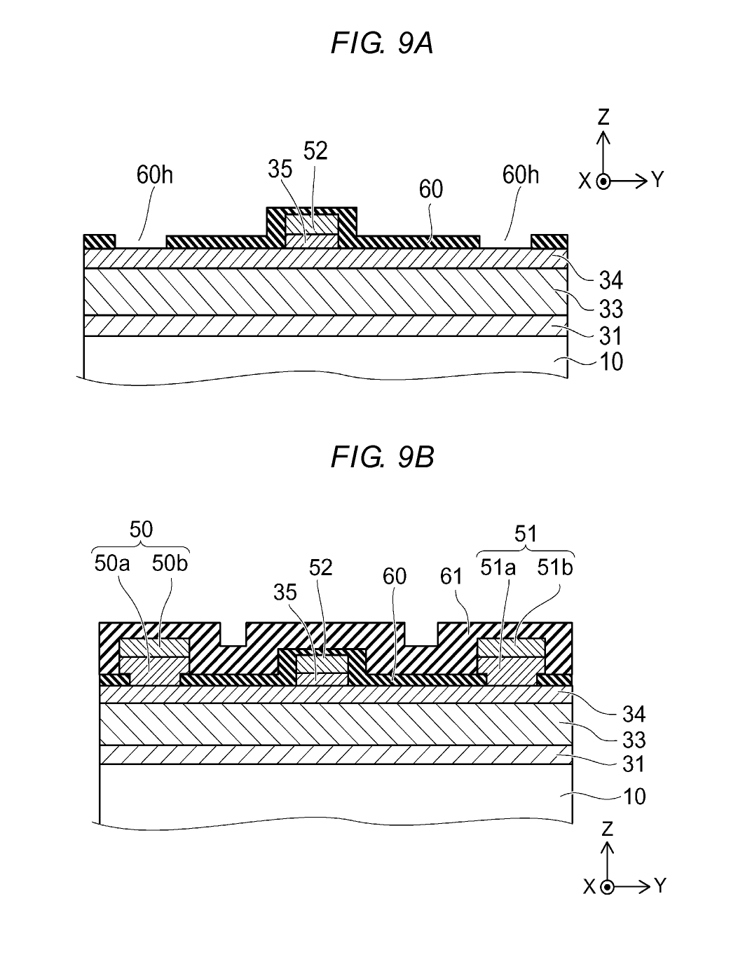

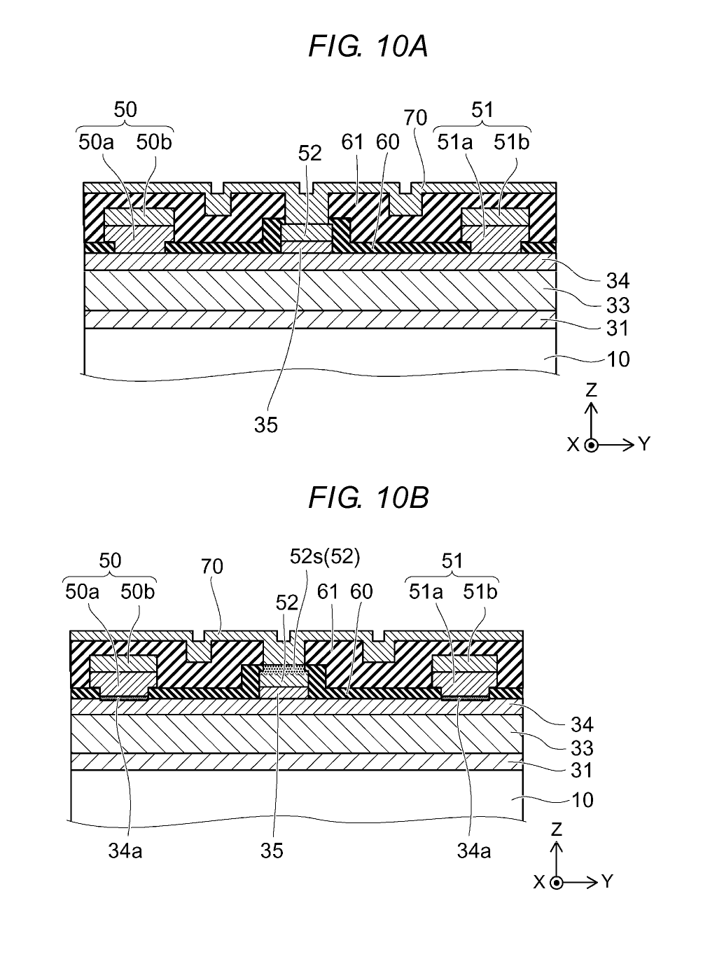

FIGS. 9A to 10B are schematic cross-sectional views illustrating a main portion of a semiconductor device according to a third embodiment.

For example, as illustrated in FIG. 9A, the p-type GaN layer 35 is selectively formed on the barrier layer 34, and the gate electrode 52 containing the p-type silicon is formed over the p-type GaN layer 35. Further, the protective layer 60 is formed on the barrier layer 34 and the gate electrode 52. The protective layer 60 is provided with openings 60h. The openings 60h are formed at the respective positions of forming the source electrode 50 and the drain electrode 51.

As illustrated in FIG. 9B, the source electrode 50 and the drain electrode 51 connected to the barrier layer 34 are formed through the openings 60h. Further, the interlayer insulating layer 61 is formed on the protective layer 60, including the portion thereof over the gate electrode 52, the source electrode 50, and the drain electrode 51.

Then, as illustrated in FIG. 10A, the interlayer insulating layer 61 and the protective layer 60 covering the gate electrode 52 are opened and a metal film 70 is formed on the interlayer insulating layer 61 and the gate electrode 52.

As illustrated in FIG. 10B, after the source electrode 50, the drain electrode 51, the barrier layer 34, the metal film 70, and the gate electrode 52 are heated, metal is diffused from the source electrode 50 into the surface of the barrier layer 34 and from the drain electrode 51 into the surface of the barrier layer 34. That is, a barrier layer 34a containing the metal is formed between the source electrode 50 and the barrier layer 34 and between the drain electrode 51 and the barrier layer 34, the upper side of the gate electrode 52 is formed into silicide, and the gate electrode 52 containing the metal is formed.

As mentioned above, in this third embodiment, the source electrode 50 and the drain electrode 51 are formed before forming the gate electrode 52 into silicide. Owing to this, the contact annealing processing and the annealing processing for forming the gate electrode 52 into silicide may be performed simultaneously. Accordingly, the number of the annealing processes is reduced and the cost may be reduced.

### Fourth Embodiment

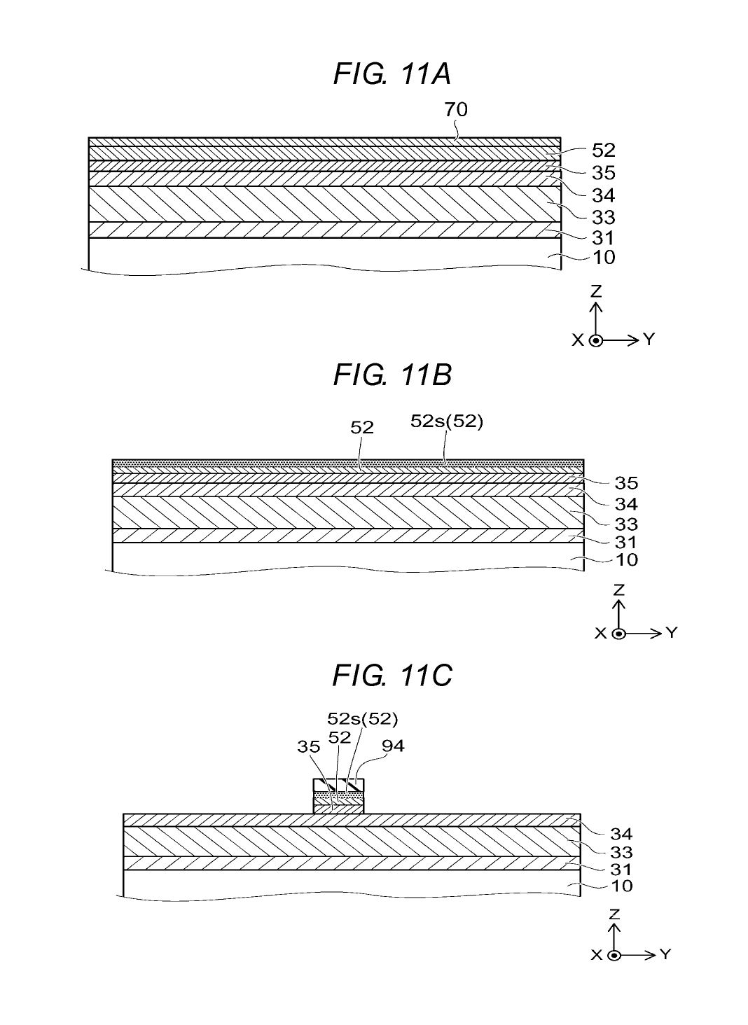

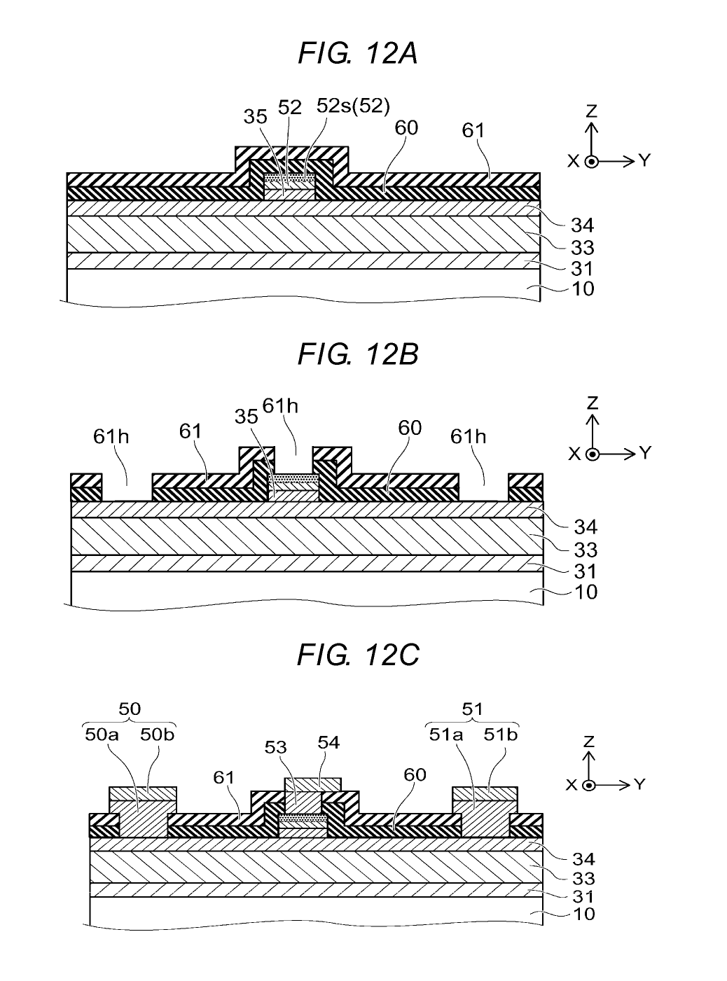

FIGS. 11A to 12C are schematic cross-sectional views illustrating the manufacturing process of a main portion of a semiconductor device according to a fourth embodiment.

For example, as illustrated in FIG. 11A, the carrier transport layer 33, the barrier layer 34, the p-type GaN layer 35, and the material to form the gate electrode 52 containing p-type polysilicon are formed on the substrate 10 over the buffer layer 31. Further, a metal film 70 is formed on the gate electrode 52.

As illustrated in FIG. 11B, the gate electrode 52 and the metal film 70 are heated and a silicide layer 52s is resultantly formed by reaction therebetween as the upper side of the gate electrode 52.

As illustrated in FIG. 11C, the portions of the material for forming the gate electrode 52 and the p-type GaN layer 35 therebelow which are not covered by the mask layer 94 are removed by RIE, and the gate electrode 52 and the p-type GaN layer 35 are thus selectively formed on the barrier layer 34. Then, the mask layer 94 is removed.

As illustrated in FIG. 12A, the protective layer 60 is formed on the barrier layer 34 and the gate electrode 52. Further, the protective layer 61 is formed on the protective layer 60.

Next, as illustrated in FIG. 12B, openings 61h are formed on the protective layers 60 and 61. The openings 61h are formed at the respective positions of forming the source electrode 50, the drain electrode 51, and the gate electrode 52.

Thereafter, as illustrated in FIG. 12C, the source electrode 50 (barrier 50a and electrode 50b) and the drain electrode 51 (barrier 51a and electrode 51b) connected to the barrier layer 34 are formed, a contact electrode 53 and a gate field plate 54 is formed on the gate electrode 52, and a gate field plate 54 is formed on the contact electrode and over an adjacent portion of the protective layer 61. Here, the barriers 50a and 51b and the contact electrode 53 contain the same material. Further, the electrodes 50b and 51b and the gate field plate 54 contain the same material.

According to the fourth embodiment, the openings 61h for forming the barriers 50a and 51a and the contact electrode 53 may be formed simultaneously. The barriers 50a and 51b and the contact electrode 53 may be formed simultaneously. Further, the electrodes 50b and 51b and the gate field plate 54 may be formed simultaneously.

In the embodiment, “on” in the case of the expression of “A is provided on B” means the case where “A is in contact with B and upper than B” as well as the case where “A is not in contact with B but just upper than B”. Further, the expression of “A is provided on B” is also applied to the case where A is under B with A and B inverted and the case where A and B are aligned alongside. This is because even if rotating the semiconductor device according to the embodiment, the structure of a semiconductor device never changes before and after the rotation.

As mentioned above, the embodiments have been described with reference to the concrete example. The embodiment is not restricted to the above example. In other words, modifications properly made by those skilled in the art are to be included in the scope of the embodiment as far as they have the characteristics of the embodiment. Each element contained in each concrete example as mentioned above and its position, material, condition, shape, and size are not restricted to the illustrated ones but may be properly changed.

Further, each element contained in the above mentioned embodiment may be properly combined with each other as far as technically permitted and their combination is to be included in the scope of the embodiment as far as it has the characteristics of the embodiment. Other, within the spirit of the embodiment, various changes and modifications may be easily arrived at by those skilled in the art, and it should be noted that all such changes and modifications are within the scope of the embodiment.

Further, in the specification, “nitride semiconductor” is intended to include all the semiconductors with the composition ratio of x, y, and z various within each range in the chemical formula BₓIn_{y}Al_{z}Ga_{1-x-y-z}N (0≦x≦1, 0≦y≦1, 0≦z≦1, x+y+z≦1). Further, in the above chemical formula, it should be noted that the compound further including the V group element other than N (nitrogen), the compound further including various doped elements in order to control various physical property such as conductivity, and the compound further including various elements not intended may be included in “nitride semiconductor”.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first nitride semiconductor layer;
a second nitride semiconductor layer on the first nitride semiconductor layer;
a first electrode on the second nitride semiconductor layer;
a second electrode on the second nitride semiconductor layer;
a p-type third nitride semiconductor layer on the second nitride semiconductor layer, at a location between the first electrode and the second electrode, and in contact with the second nitride semiconductor layer; and
a third electrode comprising p-type polysilicon on the third nitride semiconductor layer and in contact with the third nitride semiconductor layer.

2. The device according to claim 1, wherein
the third electrode further comprises metal.

3. The device according to claim 2, wherein
a concentration of the metal in an upper end of the third electrode is higher than a concentration of the metal in a lower end of the third electrode.

4. The device according to claim 3, wherein the metal and at least a portion of the polysilicon of the third electrode form a metal silicide.

5. The device according to claim 3, wherein the metal comprises at least one of nickel or titanium.

6. The device according to claim 1, wherein the p-type third nitride semiconductor layer comprises gallium nitride.

7. The device according to claim 1, further comprising an ohmic contact between the p-type polysilicon third electrode and the p-type third nitride semiconductor layer.

8. The device according to claim 1, wherein the contact resistance between the p-type polysilicon third electrode and the p-type third nitride semiconductor layer is 1×10⁻³ Ω·cm² or less.

9. A method of manufacturing a semiconductor device comprising:
providing a first nitride semiconductor layer;
forming a second nitride semiconductor layer on the first nitride semiconductor layer;
forming a p-type third nitride semiconductor layer on a portion of the second nitride semiconductor layer;
forming a first electrode and a second electrode on the second nitride semiconductor layer, such that the third semiconductor layer is between, and spaced from, the first electrode and the second electrode;
forming a third electrode, comprising p-type polysilicon, on the third nitride semiconductor layer;
forming a metal film on the third electrode; and
heating the first electrode, the second electrode, the second nitride semiconductor layer, the metal film, and the third electrode to form a metal containing nitride semiconductor layer between the first electrode and the second nitride semiconductor layer, between the second electrode and the second nitride semiconductor layer, and between the third electrode comprising the p-type polysilicon and the metal film formed on the third electrode.

10. The method according to claim 9, further comprising:
heating the third electrode such that the concentration of the metal film formed on the third electrode is at a higher concentration in an upper end of the third electrode than in a lower end of the third electrode.

11. The method according to claim 9, wherein the heating of the third electrode and the metal film formed on the third electrode is undertaken before forming the first and second electrodes on the second nitride semiconductor layer.

12. The method according to claim 9, wherein a further heating of the third electrode metal film formed on the third electrode is undertaken after forming the first and second electrodes on the second nitride semiconductor layer.

13. The method according to claim 9, wherein the heating of the first electrode, the second electrode, the second nitride semiconductor layer, the metal film, and the third electrode to form a metal containing nitride semiconductor layer between the first electrode and the second nitride semiconductor layer, between the second electrode and the second nitride semiconductor layer, and between the third electrode comprising the p-type polysilicon and the metal film formed on the third electrode, occur simultaneously.

14. The method according to claim 9, wherein an ohmic contact is formed between the p-type polysilicon third electrode and the p-type third nitride semiconductor layer.

15. The method according to claim 9, wherein the contact resistance between the p-type polysilicon third electrode and the p-type third nitride semiconductor layer is 1×10⁻³ Ω·cm² or less.

16. The method according to claim 9, wherein
the p-type third nitride semiconductor layer on a portion of the second nitride semiconductor layer and the third electrode, comprising p-type polysilicon, located on the third nitride semiconductor layer, are defined simultaneously using reactive ion etching.

17. A semiconductor device, comprising:
a substrate;
a buffer layer disposed on the substrate;
a carrier layer disposed on the buffer layer;
a barrier layer disposed on the carrier layer;
a first p-type layer disposed on a portion of the barrier layer; and
a second p-type layer of a different material than the than the first p-type layer disposed on the first p-type layer and forming an ohmic contact therewith.

18. The device of claim 17, wherein the first p-type layer comprises gallium nitride and the second p-type layer comprises polysilicon.

19. The device of claim 18, wherein the second p-type layer comprising polysilicon further comprises a metal non-uniformly distributed therein.

20. The device of claim 19, wherein the concentration of the metal in the second p-type layer changes in the depth direction of the second p-type layer.
